(19) United States
(12) Patent Application Publication
(10) Pub. No.: US 2013/0109145 A1
(43) Pub. Date: May 2, 2013

(54) METHOD OF MANUFACTURING SEMICONDUCTOR DEVICE

(71) Applicant: FUMITAKE MIENO, Shanghai (CN)

(72) Inventor: FUMITAKE MIENO, Shanghai (CN)

(73) Assignee: Semiconductor Manufacturing International (Shanghai) Corporation, Shanghai (CN)

(21) Appl. No.: 13/467,934

(22) Filed: May 9, 2012

(30) Foreign Application Priority Data
May 12, 2011 (CN) 201110121644.2

(51) Int. Cl. H01L 29/66

(52) U.S. Cl. CPC H01L 29/66477
USPC 438/305

(57) ABSTRACT

A method for manufacturing a stressed CMOS device includes providing a substrate having a dummy gate and an insulating material layer formed thereon. The dummy gate is embedded in the insulating material layer. The method further includes removing the dummy gate to form a gate opening in the insulating material layer, and implanting carbon ions through the opening to form a stressed NMOS channel and/or implanting germanium/antimony/xenon ions to form a stressed PMOS channel, using the insulating material layer as a mask. The method does not require the use of multiple masks that may cause misalignment in the channel regions.

### CROSS-REFERENCES TO RELATED APPLICATIONS

This application is based upon and claims the benefit of priority from Chinese Patent Application No. CN201110121644.2, filed on May 12, 2011, which is incorporated by reference herein in its entirety.

### BACKGROUND OF THE INVENTION

1. Field of the Disclosure

This disclosure relates to semiconductor technology, and particularly to a method for manufacturing a semiconductor device.

2. Description of the Related Art

With the development of semiconductor technology, characteristic dimension of MOSFET is continually reduced, and carrier mobility is continuously increased. Many solutions of carrier mobility enhancement have been proposed.

Some of such solutions improve carrier mobility by applying stress to the channel region of MOSFET.

By applying stress to the channel region of a MOS device, carrier mobility can be significantly improved. Channel stress engineering for NMOS is different from PMOS. Specifically, an NMOS device involves the movement of electrons for conducting. The larger the lattice spacing is, the less electrons scatter on the lattice, resulting in higher electron mobility and a larger driving current. Therefore, it is desirable to apply a tensile stress to the NMOS channel to enlarge the crystal lattice. As to a PMOS device, on the contrary, the smaller the lattice spacing is, the closer is the lattice hole distance, resulting in higher hole mobility. Therefore, it is desirable to apply a compressive stress to the PMOS channel.

A germanium atom is slightly larger than a silicon atom. When a GeSi crystal is formed, a certain percentage of silicon atoms in a GeSi substrate is replaced by germanium atoms, thus a compressive stress will be generated in the GeSi lattice. On the other hand, a carbon atom is smaller than a silicon atom. When a SiC crystal is formed, a certain percentage of silicon atoms in a SiC substrate are replaced by carbon atoms, then a tensile stress will be generated in the SiC lattice.

The electrical properties of a GeSi channel region of a PMOSFET transistor formed by germanium ion implantation have been described in the paper of Jiang, Hong and Elliman, R. G. “Electrical properties of GeSi Surface- and Buried-Channel p-MOSFET's Fabricated by Ge Implantation”, IEEE TRANSACTIONS ON ELECTRON DEVICES, VOL. 43, No. 1 January 1996, PAGE 97-103. FIG. 3 is the diagram in that paper showing a method of forming the GeSi channel region (remarks in this diagram have been removed). The method of forming the GeSi channel region proposed in that paper will be discussed below with reference to FIG. 3.

First, a SiO₂ layer of 0.8 μm thick is formed on an n-Si substrate having (100) crystal plane. An opening is formed in the SiO₂ layer to expose a portion of the substrate to be formed as the channel region. With reference to FIG. 3 (a), Ge ions are implanted through the opening into the substrate so as to form a GeₓSi₁₋ₓ channel region.

Then, a part of the SiO₂ layer is removed, a photoresist pattern is formed above the GeₓSi₁₋ₓ channel region, and source and drain regions are formed by B ion implantation.

Next, with reference to FIG. 3 (b), the photoresist is removed, and B ions are implanted into the channel region.

Next, with reference to FIG. 3 (c), a SiO₂ layer having a thickness of 0.6 μm is deposited by PECVD, and then As ions are doped into the back of the substrate.

Then, with reference to FIG. 3 (d), the SiO₂ layer above the channel region is thinned.

Then, contact holes to source and drain regions are formed, and aluminum is deposited and etched so as to form contacts to the source region, the drain region and the gate.

In the above method, it is necessary to use masks corresponding to the channel region at least three times: one for forming the opening as shown in FIG. 3 (a); one for forming the photoresist pattern shown in FIG. 3 (b); and one for thinning the SiO₂ layer above the channel region as shown in FIG. 3 (d).

However, it is difficult to align these three mask patterns with each other. Therefore, it is desirable to provide a simple method for forming a semiconductor device having a strained channel region.

### BRIEF SUMMARY OF THE INVENTION

According to a first aspect of this disclosure, a method of manufacturing a semiconductor device includes providing a substrate, forming an insulating material layer over the substrate, and forming a dummy gate embedded in the insulating material layer. The method further includes removing the dummy gate to form an opening in the insulating material layer and forming a stress layer by implanting a plurality of ions through the opening into the substrate using the insulating material layer as a mask.

In an embodiment, the plurality of ions comprises carbon to form an NMOS device. In a preferred embodiment, the plurality of carbon ions is implanted by using C₇Hₓ, with an implantation energy ranging from 1 to 2 keV, and an ion implantation dose ranging from 0.3×10¹⁴ to 1.0×10¹⁴ cm⁻². In a preferred embodiment, the plurality of ions for forming NMOS comprises indium ions, implanted with an implantation energy of 5 to 14 keV and a dose of about 5×10¹³ to about 1×10¹⁴ cm⁻². In a specific embodiment, implanting the plurality of ions further comprises implanting xenon through the opening into the substrate, with an implantation energy of 5 to 20 keV, and a dose ranging from 1×10¹³ to 1×10¹⁴ cm⁻².

In an embodiment, the plurality of ions comprises germanium to form a PMOS device. In a preferred embodiment, the plurality of germanium ions for forming the PMOS device is implanted with an implantation energy ranging from 2 to 20 keV and an ion implantation dose ranging from 0.5×10¹⁶ to 6.0×10¹⁶ cm⁻². In a preferred embodiment, the plurality of ions for forming the PMOS device further comprises antimony that is implanted with an implantation energy of 5 to 14 keV and a dose of 5×10¹³ to 1×10¹⁴ cm⁻². In a specific embodiment, implanting the plurality of ions for forming PMOS further comprises implanting xenon through the opening into the substrate, with an implantation energy of 5 to 20 keV and a dose of 1×10¹³ to 1×10¹⁴ cm⁻².

In one embodiment, the method further comprises performing annealing after implanting the plurality of ions.

In another embodiment, the method further comprises forming a dummy gate oxide layer under the dummy gate.

In one embodiment, the annealing is performed by using a long pulse flash light. In a preferred embodiment, the long pulse flash annealing process is performed with a pulse duration of 2 to 8 ms at a substrate temperature of 800 to 1200° C.

In one embodiment, the long pulse flash light has a wavelength that can be absorbed by the dummy gate oxide layer.

In one embodiment, the method further comprises performing an oxidation process after performing annealing. More preferably, the method further comprises removing the dummy gate oxide layer after performing annealing process.

In one embodiment, the method further comprises performing an oxidation process after implanting the plurality of ions.

In one embodiment, the oxidation process is performed by using a rapid thermal oxidation process for 0.5 to 2 min at a temperature of 700 to 850° C.

In one embodiment, the method further comprises removing the oxide in the opening, depositing a high dielectric constant material, and a metal gate material to form a metal gate.

In one embodiment, the method further comprises performing a surface treatment to reduce surface roughness before depositing the high dielectric constant material.

In a preferred embodiment, the surface treatment is performed by annealing at a temperature lower than 850° C. in a hydrogen ambience, or the surface treatment is performed by annealing at a temperature lower than 650° C. in a HCl vapor ambience.

In one embodiment, the method further comprises: performing implantation on the substrate by using the dummy gate as a mask, to form lightly doped regions on opposite sides of the dummy gate; forming sidewall spacers on two sidewalls of the dummy gate opposed to each other; performing implantation on the substrate by using the sidewall spacers as a mask, to form source and drain regions on the opposite sides of the dummy gate, respectively; depositing an insulating material on the substrate to cover the substrate and the dummy gate; and performing chemical mechanical polishing to make the upper surface of the insulating material flush with the upper surface of the dummy gate.

According to the manufacturing method in this disclosure, the misalignment problem resulted from the use of multiple masks corresponding to the channel region can be avoided.

### BRIEF DESCRIPTION OF THE DRAWINGS

The accompanying drawings illustrate embodiments of the disclosure and, together with the description, serve to explain the principles of the disclosure.

Note that, in these drawings, various parts are not drawn to scale for the sake of clarity.

FIGS. 1A-1E show in cross-sectional views the steps of a method of manufacturing a gate structure according to an exemplary embodiment of this disclosure;

FIGS. 2A-2D show in cross-sectional views steps of an exemplary method of forming the structure shown in FIG. 1A respectively; and

FIG. 3 is a diagram showing a method of forming a GeSi channel region according to a current technique.

### DETAILED DESCRIPTION OF THE INVENTION

The method of manufacturing a semiconductor device according to this disclosure will be described with reference to the drawings hereinafter.

At present, the manufacturing process of a transistor having a HKMG (a high dielectric constant insulating layer and a metal gate) structure with the replacement gate built is referred to as a “gate last process”.

In a gate last process, a sacrificial gate—the dummy gate is formed first. An opening corresponding to the channel region is formed after the dummy gate is removed. In one embodiment of this disclosure, germanium is implanted through this opening in a self aligned process, without an additional mask.

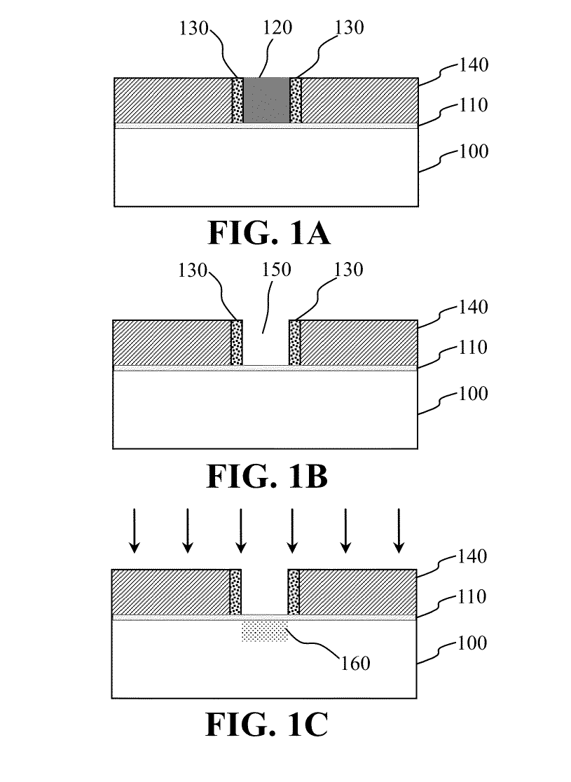

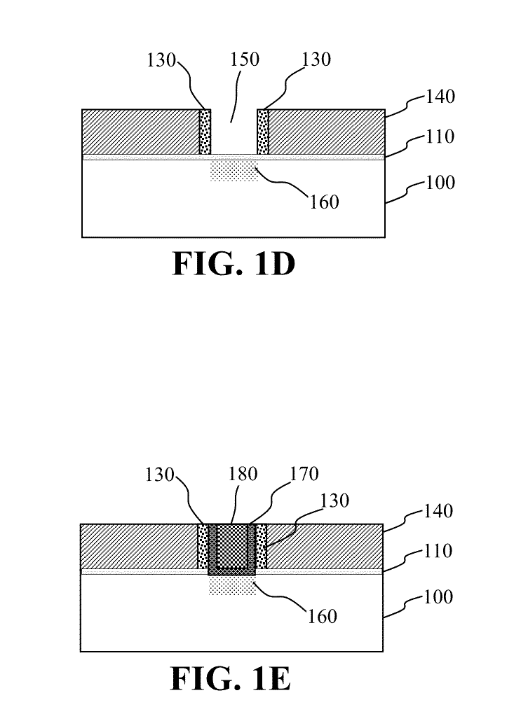

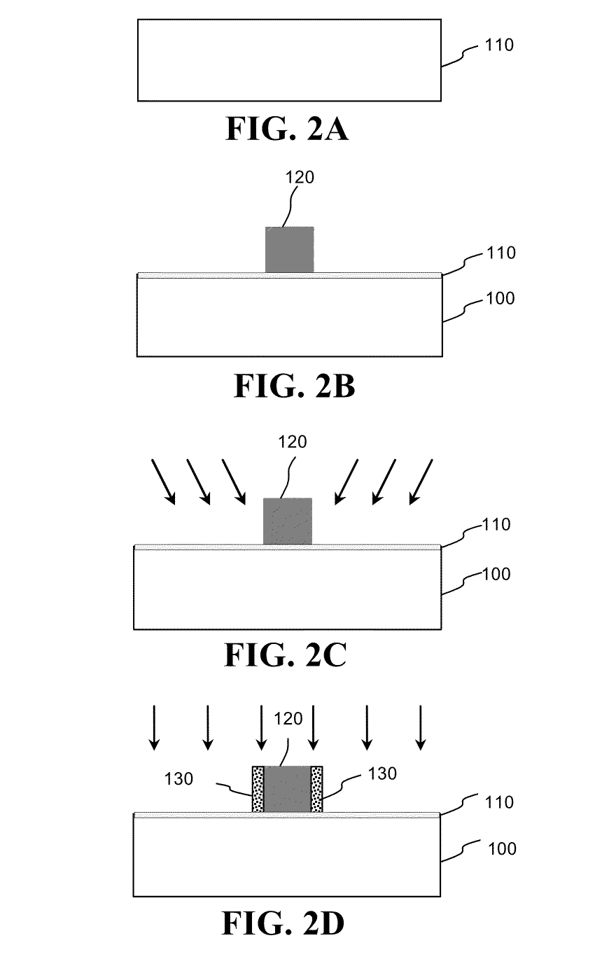

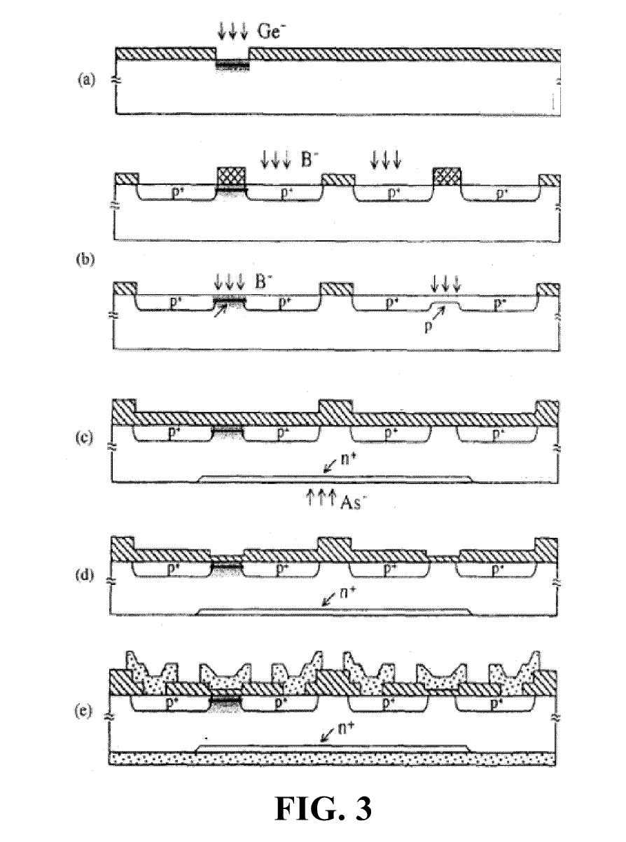

A method of manufacturing a semiconductor device according to this disclosure is described with reference to FIGS. 1A-1E and FIGS. 2A-2D.

First, as shown in FIG. 1A, a substrate 100 is provided. A dummy gate 120 and an insulating material layer 140 are formed over the substrate. The dummy gate 120 is embedded in the insulating material layer 140. The upper surface of the dummy gate 120 may be flush (coplanar) with the upper surface of the insulating material layer 140. A source/drain implantation is performed on the substrate on both sides of the dummy gate. Sidewall spacers 130 may be formed on the sides of the dummy gate 120 to define heavily doped regions for source/drain implantation.

An insulating film 110, such as an oxide layer, may be formed between the substrate 100 and the dummy gate 120 and between the substrate 100 and the insulating material layer 140. The portion of the insulating film 110 between the dummy gate 120 and the substrate 100 can be referred to as a “dummy gate insulating film” or a “dummy gate oxide layer”.

Next, an exemplary process for making the structure shown in FIG. 1A will be described with reference to FIGS. 2A-2D.

As shown in FIG. 2A, at first, a substrate is prepared for fabricating the semiconductor device.

In order to improve both a channel mobility for a NMOS device and a channel mobility for a PMOS device, “hybrid substrate orientation” technique is applied by, for example, wafer bonding. A substrate having a (100) crystal plane may be used for an NMOS device and another substrate having a (110) crystal plane may be used for a PMOS device. For purpose of description, substrate 100 shown in FIGS. 2A-2D has a (100) crystal plane.

Then, as shown in FIG. 2B, an oxide layer 110 and a dummy gate 120 are formed on the substrate 100.

Next, as shown in FIG. 2C, ion implantation is performed on the substrate by using the dummy gate 120 as a mask, to form two lightly doped regions (LDD) on the opposite sides of the dummy gate.

Next, as shown in FIG. 2D, for example, a silicon nitride layer is deposited and etched to form sidewall spacers 130 on two sidewalls of the dummy gate 120 opposed each other. Then, implantation is performed on the substrate by using the sidewall spacers as a mask, so as to form source and drain regions on the opposite sides of the dummy gate.

Then, an insulating material is deposited to cover the substrate and the dummy gate, and chemical mechanical polishing is performed to coplanarize the upper surface of the insulating material flush and the upper surface of the dummy gate 120 to obtain the structure shown in FIG. 1A.

The method of manufacturing the semiconductor device according to this disclosure will be discussed below.

As shown in FIG. 1B, the dummy gate 120 is removed and an opening 150 is formed in the insulating material layer 140.

Then, as shown in FIG. 1C, carbon (for NMOS) or germanium (for PMOS) ions are implanted through the opening 150 into the substrate 100 by using the insulating material layer 140 (and the sidewall spacers 130, if any) as a mask.

Typically, carbon ions are implanted into a region of the substrate where the NMOS device is to be formed. Germanium ions are implanted into a region of the substrate where the PMOS device is to be formed.

If performance improvement of the PMOS device is more critical, germanium ions will be implanted into the PMOS region, and the NMOS region will be shielded from being implanted.

The NMOS region may be shielded with a photoresist, leaving the PMOS region exposed, for the germanium implant into the PMOS region.

On the other hand, if performance improvement of the NMOS device is more critical, carbon ions are implanted into the NMOS region, and the PMOS region will be shielded from being implanted.

The PMOS region may be shielded with a photoresist, leaving the NMOS region exposed, for the carbon implant into the NMOS region.

Alternatively, if performance improvement is desired for both of the NMOS and PMOS devices, corresponding implantations may be performed separately in the PMOS and NMOS regions.

In the present embodiment, since the dummy gate oxide layer is not removed, carbon ions or germanium ions are implanted through the dummy gate oxide layer into the substrate 100.

Germanium ions are implanted into a region of the substrate where a PMOS device is to be formed. The implantation energy of germanium ions may be 10 to 30 keV, and the ion implantation dose may be 0.5×10¹⁶ to 6.0×10¹⁶ cm⁻².

In the region of the substrate where the PMOS device is to be formed, n-type impurity ions may be additionally implanted through the opening 150 into the substrate 100, in order to further adjust the threshold voltage. For example, the n-type impurity ions may be antimony (Sb) ions, the implantation energy may be 5 to 14 keV, and the ion implantation dose may be 5×10¹³ to 1×10¹⁴ cm⁻².

In the region of the substrate where the NMOS device is to be formed, carbon ions may be implanted by using C₇Hₓ. The implantation energy of carbon ions may be 2 to 5 keV, and the ion implantation dose may be 0.5×10¹⁴ to 1.2×10¹⁴ cm⁻².

In the region of the substrate where the NMOS device is to be formed, p-type impurity ions may be additionally implanted through the opening 150 into the substrate 100, in order to further adjust the threshold voltage. For example, the p-type impurity ions may be indium (In) ions, the implantation energy may be 5 to 14 keV, and the ion implantation dose may be 5×10¹³ to 1×10¹⁴ cm⁻².

Additionally, xenon may be implanted through the opening 150 into the substrate 100 in both of the region where the PMOS device is to be formed and the region where the NMOS device is to be formed, in order to amorphize the silicon crystal in the channel region, and thus facilitate a subsequent recrystallization. The implantation energy may be 5 to 20 keV, and the ion implantation dose may be 1×10¹³ to 1×10¹⁴ cm⁻².

In another embodiment, the dummy gate insulating film may be removed when or after removing the dummy gate 120. In this case, in a region of the substrate where a PMOS device is to be formed, the implantation energy of germanium ions may be 2 to 20 keV, and the ion implantation dose may be 0.5×10¹⁶ to 6.0×10¹⁶ cm⁻²; in a region of the substrate where an NMOS device is to be formed, carbon ions may be implanted by using C₇Hₓ, and the implantation energy may be 1 to 2 keV, and the ion implantation dose may be 0.3×10¹⁴ to 1.0×10¹⁴ cm⁻².

Next, as shown in FIG. 1D, annealing and/or oxidation may be performed to activate the implanted ions, thereby forming SiGe crystal with compressive stress (for PMOS device) or SiC crystal with tensile stress (for NMOS device).

Since a Ge atom is larger than a Si atom, when some Si atoms in the original Si crystal are replaced by Ge atoms in the channel region of the PMOS device, a SiGe crystal having compressive stress is formed, and the hole carrier mobility can be improved advantageously. In addition, for the PMOS device, since the threshold voltage of the SiGe channel region is lower than that of the Si channel region, the threshold voltage can be lowered by forming the SiGe channel region.

Since a C atom is smaller than a Si atom, when some Si atoms in the original Si crystal are replaced by C atoms in the channel region of the NMOS device, a SiC crystal having tensile stress is formed, and the electron carrier mobility can be improved advantageously. In addition, for the NMOS device, since the threshold voltage of the SiC channel region is lower than that of the Si channel region, the threshold voltage can be lowered by forming the SiC channel region.

A long pulse flash annealing process may be performed with pulse duration of 2 to 8 ms at a substrate temperature of 800 to 1200° C.

In performing the annealing process, if the dummy gate oxide layer remains, it may act as a cover layer. It is possible to enhance the annealing effect, if the light used in the long pulse flash annealing process has a wavelength in an absorption spectrum of the cover layer.

The oxidation process may be performed by using a rapid thermal oxidation process for 0.5 to 2 min at a temperature of 700 to 850° C. Before performing the oxidation process, for example, when or after removing the dummy gate 120, if the dummy gate oxide layer is removed, then a better effect can be obtained.

If an oxidation process is additionally performed after the annealing process, a better effect can be obtained by combining the two processes.

Next, as shown in FIG. 1E, the portion of the oxide layer exposed in the opening 150 is removed, and then a high dielectric constant material and a metal gate material are deposited to form a metal gate. Here, the portion of the oxide layer may comprise the dummy gate oxide layer mentioned previously (if it is not removed), and may also comprise new oxides formed during subsequent operations, such as, during the oxidation process.

A surface treatment may be performed to reduce surface roughness before depositing the high dielectric constant material. The surface treatment may be performed by annealing in hydrogen ambience at a temperature lower than 850° C., or may be performed by annealing in a HCl vapor ambience at a temperature lower than 650° C.

Thus, the method of manufacturing the semiconductor device according to this disclosure and the obtained semiconductor device have been described in detail. In order not to obscure the concept of this disclosure, some details that are well known in the art are not described. According to the above description, those skilled in the art can thoroughly understand how to implement the technical solutions disclosed herein.

The above description is given merely for illustration and explanation, which is not exhaustive, and not intended to limit the disclosure to the disclosed form. Many modifications and variations are obvious to those skilled in the art. Embodiments are selected and described in order to explain the principle and practical application of this disclosure, so that those skilled in the art can understand this disclosure and envisage various embodiments with various modifications suitable to specific usages.

1. A method of manufacturing a semiconductor MOS device, comprising:
forming a substrate;
forming an insulating material layer over the substrate;
forming a dummy gate embedded in the insulating material layer;
removing the dummy gate to form an opening in the insulating material layer;
forming a stress region by implanting ions through the opening into the substrate using the insulating material layer as a mask.

2. The method according to claim 1, wherein the ions comprise carbon ions to form an NMOS device.

3. The method according to claim 2, wherein the carbon ions are implanted using C₇Hₓ with an implantation energy ranging from 2 to 5 keV and an ion implantation dose ranging from 0.5×10¹⁴ to 1.2×10¹⁴ cm⁻².

4. The method according to claim 1, wherein the ions comprise germanium ions to form a PMOS device.

5. The method according to claim 4, wherein the germanium ions are implanted with an implantation energy ranging from 10 to 30 keV and an ion implantation dose ranging from 0.5×10¹⁶ to 0.6×10¹⁶ cm⁻².

6. The method according to claim 4, wherein the ions for forming the PMOS device further comprise antimony, implanted with an implantation energy ranging from 5 to 14 keV and a dose ranging from 5×10¹³ to 1×10¹⁴ cm⁻².

7. The method according to claim 2, wherein the ions for forming a NMOS device further comprise indium ions, implanted with an implantation energy ranging from 5 to 14 keV and a dose ranging from 5×10¹³ to 1×10¹⁴ cm⁻².

8. The method according to claim 4, wherein implanting the ions for forming the PMOS device further comprises implanting xenon through the opening into the substrate with an implantation energy ranging from 5 to 20 keV and a dose ranging from 1×10¹³ to 1×10¹⁴ cm⁻².

9. The method according to claim 1, further comprising forming a dummy gate oxide layer under the dummy gate.

10. (canceled)

11. The method according to claim 9, wherein the annealing is performed by using a long pulse flash light, wherein the flash light has a wavelength that can be absorbed by the dummy gate oxide layer.

12. The method according to claim 11, wherein the long pulse flash annealing process is performed with a pulse duration of 2 to 8 ms at a substrate temperature of 800 to 1200 C.

13. (canceled)

14. The method according to claim 9, further comprising performing an oxidation process after performing annealing.

15. The method according to claim 14, further comprising removing the dummy gate oxide layer after performing annealing process to form an NMOS device, wherein the carbon ions may be implanted by using C₇Hₓ, and the implantation energy may be 1 to 2 keV, and the ion implantation dose may be 0.3×10¹⁴ to 1.0×10¹⁴ cm⁻².

16. The method according to claim 1, further comprising performing an oxidation process after implanting the ions.

17. The method according to claim 16, wherein the oxidation process is performed by using a rapid thermal oxidation process for 0.5 to 2 min at a temperature of 700 to 850° C.

18. The method according to claim 9, further comprising:
removing a portion of the dummy gate oxide layer exposed in the opening; and
depositing a high dielectric constant material and a metal gate material to form a metal gate.

19. The method according to claim 18, further comprising performing a surface treatment to reduce surface roughness before depositing the high dielectric constant material.

20. The method according to claim 19, wherein the surface treatment is performed by annealing at a temperature lower than 850° C. in a hydrogen ambience.

21. The method according to claim 19, wherein the surface treatment is performed by annealing at a temperature lower than 650° C. in a HCl vapor ambience.

22. The method according to claim 1, further comprising:
Performing a first implantation into the substrate by using the dummy gate as a mask to form lightly doped regions on opposite sides of the dummy gate;
forming sidewall spacers on opposite sides of the dummy gate;
performing a second implantation into the substrate by using the sidewall spacers as a mask to form source and drain regions on the opposite sides of the dummy gate;
depositing an insulating material on the substrate to cover the substrate and the dummy gate; and
coplanarizing an upper surface of the insulating material and an upper surface of the dummy gate by performing a chemical mechanical polishing.

23. The method according to claim 12, further comprising removing the dummy gate oxide layer after performing annealing to form a PMOS device, wherein the implantation energy of germanium ions may be 2 to 20 keV, and the ion implantation dose may be 0.5×10¹⁶ to 6.0×10¹⁶ cm⁻².
